(19) United States
(12) Patent Application Publication
(10) Pub. No.: US 2024/0273268 A1
(43) Pub. Date: Aug. 15, 2024

(54) HOSE REMAINING SERVICE LIFE PREDICTION METHOD AND HOSE REMAINING SERVICE LIFE PREDICTION SYSTEM

(71) Applicant: BRIDGESTONE CORPORATION, Chuo-ku, Tokyo (JP)

(72) Inventors: Taisuke KURODA, Chuo-ku, Tokyo (JP); Yuji KUMAGAI, Chuo-ku, Tokyo (JP)

(21) Appl. No.: 18/568,278

(22) PCT Filed: Jun. 28, 2022
(86) PCT No.: PCT/JP2022/025805

§ 371 Date: Dec. 8, 2023

(30) Foreign Application Priority Data
Aug. 6, 2021 (JP) 2021-130275
Aug. 6, 2021 (JP) 2021-130276
Aug. 6, 2021 (JP) 2021-130277
Aug. 6, 2021 (JP) 2021-130278
Aug. 6, 2021 (JP) 2021-130279
Aug. 6, 2021 (JP) 2021-130280

(51) Int. Cl. G06F 30/28; F16L 11/08

(52) U.S. Cl. CPC G06F 30/28; F16L 11/08

(57) ABSTRACT

A hose remaining service life prediction method to predict a remaining service life of an in-service hose at least including an inner tube rubber layer configured containing rubber having an inside portion contacted by a fluid and having a physical property value that changes with time and including a reinforcement layer disposed further to an outside periphery than the inner tube rubber layer. The hose remaining service life prediction method includes a deterioration model creation process that for a hose of the same type to the in-service hose uses the fluid to find a relationship of the inner tube rubber layer between an operating time and the physical property value of the rubber and to create a deterioration model of the inner tube rubber layer, includes an operating time calculation process that for the in-service hose calculates an operating time of the inner tube rubber layer from start of use up to when the prediction is performed, and includes a remaining service life prediction process that predicts the remaining service life of the in-service hose based on the operating time calculated in the operating time calculation process and on the deterioration model created in the deterioration model creation process.

### TECHNICAL FIELD

The present disclosure relates to a hose remaining service life prediction method and to a hose remaining service life prediction system.

### BACKGROUND ART

Generally a hose including an inner tube rubber layer is employed in construction machinery, factory equipment and the like to transmit pressure using a fluid (oil or the like). In such hoses, the rubber layer gradually deteriorates with prolonged usage even when employed within a range determined by the specification of such hoses.

Sometimes a malfunction, such as fluid present inside the hose leaking out from a vicinity of a deteriorated position, occurs in a hose used beyond its service life with a deteriorating rubber layer.

There is a proposal to prevent such a malfunction by predicting, from the operating time of the hose, a remaining usable duration such that operation of the hose does not exceed the service life (see, for example, Japanese Patent Application Laid-Open (JP-A) No. 2020-186983).

### SUMMARY OF INVENTION

### Technical Problem

The present inventors have discovered from various investigations into hoses for handling fluids that an operation mode of the hose affects the service life of the hose.

In consideration of the above circumstances, an object of the present disclosure is to provide a hose remaining service life prediction method and a hose remaining service life prediction system that are capable of simply predicting the remaining service life of a hose that uses a fluid.

### Solution to Problem

A hose remaining service life prediction method according to a first aspect is a hose remaining service life prediction method that makes a prediction as to a remaining service life of an in-service hose including at least an inner tube rubber layer including a rubber having an inside portion contacted by a fluid and having a physical property value that changes with time, and a reinforcement layer disposed further toward an outer side periphery than the inner tube rubber layer. The hose remaining service life prediction method includes a deterioration model creation process that, for a same kind of hose as the in-service hose, uses the fluid to find a relationship between an operating time and the physical property value of the rubber of the inner tube rubber layer and to create a deterioration model of the inner tube rubber layer, includes an operating time calculation process, that for the in-service hose, calculates an operating time of the inner tube rubber layer from start of use until a time at which the prediction is performed, and includes a remaining service life prediction process that predicts the remaining service life of the in-service hose based on the operating time calculated in the operating time calculation process and on the deterioration model created in the deterioration model creation process.

The hose remaining service life prediction method according to the first aspect predicts the remaining service life of the in-service hose including at least the inner tube rubber layer configured containing rubber having an inside portion contacted by the fluid and having the physical property value that changes with time, and the reinforcement layer disposed further to an outside periphery than the inner tube rubber layer.

First, the deterioration model creation process uses the fluid for use in the in-service hose to find the relationship of the inner tube rubber layer between the operating time and the physical property value of the rubber for a hose of the same type to the in-service hose and to create the deterioration model of the inner tube rubber layer.

In the operating time calculation process the operating time is calculated for the in-service hose from the start of use of the inner tube rubber layer to the prediction time.

In the remaining service life prediction process, the remaining service life of the in-service hose is predicted based on the operating time calculation process, based on the operating time calculated in the operating time calculation process, and based on the deterioration model created in the deterioration model creation process.

A hose remaining service life prediction system according to an eighth aspect is a hose remaining service life prediction system that makes a prediction as to a remaining service life of an in-service hose including at least an inner tube rubber layer including aa rubber having an inside portion contacted by a fluid and having a physical property value that changes with time, and a reinforcement layer disposed further toward an outer side periphery than the inner tube rubber layer. The hose remaining service life prediction system includes a deterioration model creation section that, for a same kind of hose as the in-service hose, uses the fluid to find a relationship between an operating time and the physical property value of the rubber of the inner tube rubber layer and to create a deterioration model of the inner tube rubber layer, includes an operating time calculation section that for the in-service hose calculates an operating time of the inner tube rubber layer from start of use until a time at which the prediction is performed, and includes a remaining service life prediction section that predicts the remaining service life of the in-service hose based on the operating time calculated by the operating time calculation section and on the deterioration model created by the deterioration model creation section.

The hose remaining service life prediction system according to the eighth aspect predicts the remaining service life of the in-service hose including at least the inner tube rubber layer configured containing rubber having an inside portion contacted by a fluid and having a physical property value that changes with time, and the reinforcement layer disposed further to the outside periphery than the inner tube rubber layer.

In the deterioration model creation section, for the hose of the same type to the in-service hose, the fluid for use in the in-service hose is employed to find a relationship of the inner tube rubber layer between the operating time and the physical property value of the rubber and the deterioration model of the inner tube rubber layer is created.

In the operating time calculation section the operating time from the start of use of the inner tube rubber layer to the prediction time is calculated for the in-service hose.

The remaining service life prediction section predicts the remaining service life of the in-service hose based on the operating time calculated by the operating time calculation section and on the deterioration model created by the deterioration model creation section.

### Advantageous Effects of Invention

The hose remaining service life prediction method of the present disclosure as described above exhibits the excellent advantageous effect of being able to simply predict the remaining service life of a hose.

Moreover, the hose remaining service life prediction system of the present disclosure exhibits the excellent advantageous effect of being able to simply predict the remaining service life of a hose.

### BRIEF DESCRIPTION OF DRAWINGS

FIG. 1 is an overall perspective view illustrating an example of a hose that is to be subjected to prediction in a hose remaining service life prediction method according to an exemplary embodiment of the present disclosure and in a hose remaining service life prediction system according to an exemplary embodiment of the present disclosure, illustrated in an example of an embodiment in which the hose is installed to machinery or the like.

FIG. 2A is an exploded perspective view of part of an example of a configuration of an inside portion of the hose illustrated in FIG. 1.

FIG. 2B is an exploded perspective view of part of an example of a configuration of an inside portion of the hose illustrated in FIG. 1.

FIG. 3 is a flowchart illustrating a hose remaining service life prediction method according to a first exemplary embodiment of the present disclosure.

FIG. 4 is a schematic diagram illustrating an example of a deterioration model in the first exemplary embodiment of the present disclosure.

FIG. 5 is a schematic diagram illustrating an example of a relationship between an elongation at break of rubber and operating time.

FIG. 6 is a diagram to explain a hose remaining service life prediction system according to the first exemplary embodiment of the present disclosure.

FIG. 7 is a functional block diagram illustrating a system control configuration in the first exemplary embodiment of the present disclosure.

FIG. 8 is a schematic diagram illustrating an example of a relationship between an elongation at break of rubber and operating time.

FIG. 9 is a schematic diagram illustrating an example of a relationship between an elongation at break of rubber and operating time.

FIG. 10A is a schematic diagram illustrating an example of a relationship between an elongation at break of rubber and operating time.

FIG. 10B is a schematic diagram illustrating an example of a relationship between an elongation at break of rubber and operating time.

FIG. 11A is a side view of a hose illustrating an example of a mode of bending.

FIG. 11B is a side view of a hose illustrating an example of a mode of bending.

FIG. 12 is a schematic diagram illustrating an example of a relationship between an elongation at break of rubber and operating time.

FIG. 13A is a side view of a hose illustrating an example of a mode of bending.

FIG. 13B is a side view of a hose illustrating an example of a mode of bending.

FIG. 14 is a schematic diagram illustrating an example of a relationship between an elongation at break of rubber and operating time.

FIG. 15A is a side view of a hose illustrating an example of a mode of bending.

FIG. 15B is a side view of a hose illustrating an example of a mode of bending.

FIG. 16 is a schematic diagram illustrating an example of a relationship between an elongation at break of rubber and operating time.

FIG. 17 is a configuration diagram illustrating a hardware configuration of a server.

### DESCRIPTION OF EMBODIMENTS

### First Exemplary Embodiment

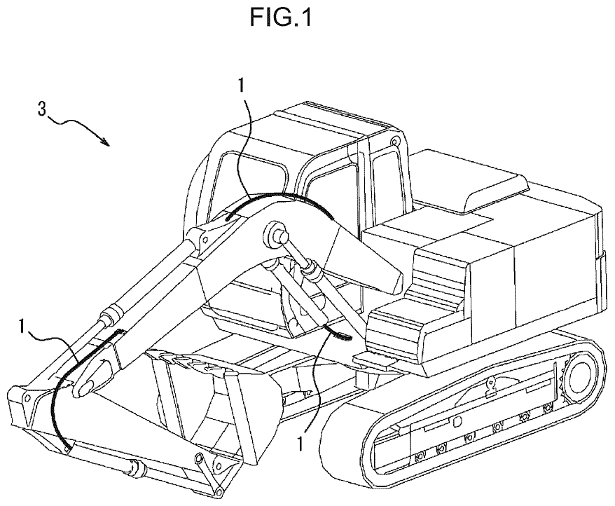

Description follows regarding a hose remaining service life prediction method and a hose remaining service life prediction system 100 according to a first exemplary embodiment of the present disclosure, with reference to FIG. 1 to FIG. 8. The first exemplary embodiment is an embodiment in which service life prediction of a hose 1 is performed for a case in which a physical property of an inner tube rubber layer 11 is changed by an additive included in a fluid.

### Hose Remaining Service Life Prediction Method According to First Exemplary Embodiment.

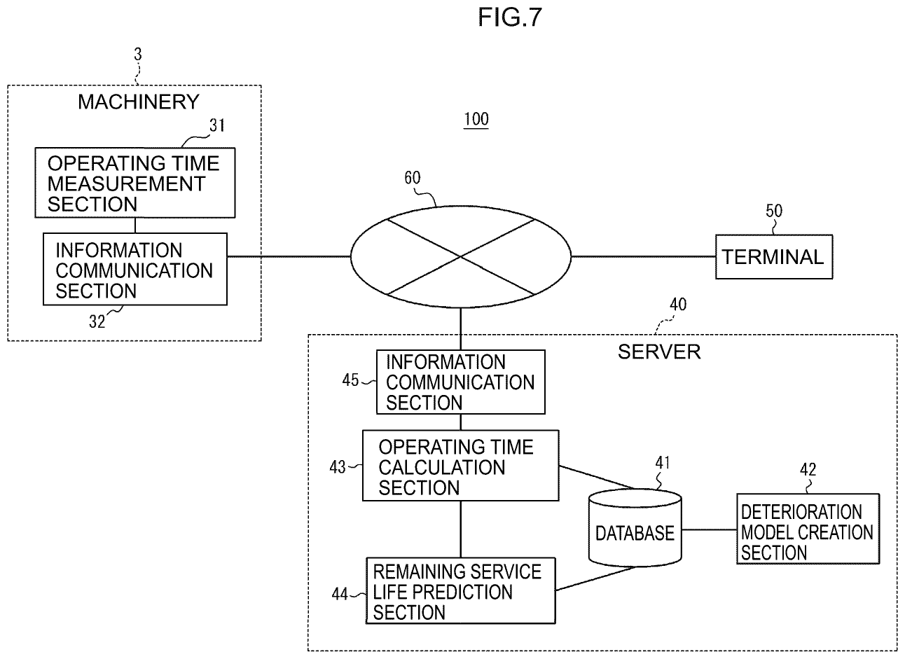

First description follows regarding the hose 1 that is applicable to the hose remaining service life prediction method according to the present exemplary embodiment and to the hose remaining service life prediction system 100 (see FIG. 7) according to the present exemplary embodiment, with reference to FIG. 1.

As illustrated in FIG. 1, the hose 1 is, for example, installed to machinery 3 (for example a construction machine as in the illustrated example, factory equipment, or the like) and is, for example, used with a high pressure fluid (oil or the like) employed to transmit pressure.

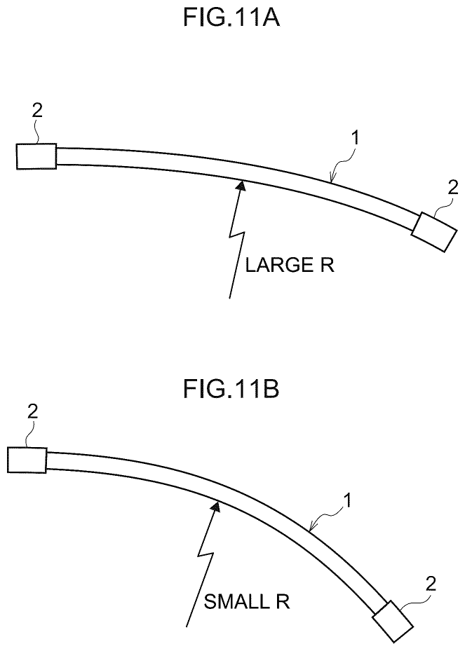

As an example as illustrated in FIG. 11, a fitting ferrule 2 for connecting to the machinery 3 may be attached to each of the two ends of the hose 1 by inserting inside and fitting outside the hose 1 before crimping. The hose 1 may be installed to the machinery 3 through these fitting ferrules 2.

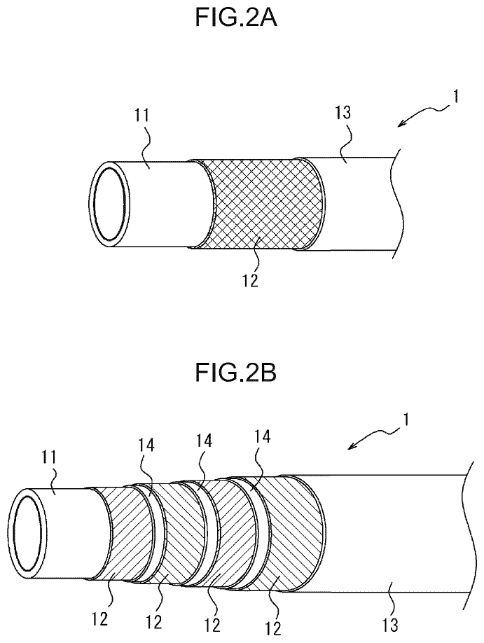

As illustrated in FIG. 2A and FIG. 2B, the hose 1 includes at least the inner tube rubber layer 11, a reinforcement layer 12 disposed further to an outside periphery than the inner tube rubber layer 11, and an outer cover layer 13 disposed further to the outside periphery than the reinforcement layer 12.

The inner tube rubber layer 11 is an innermost peripheral rubber layer, and has heat resistant properties and other properties of resistance to fluid flowing inside the inner tube rubber layer 11.

The reinforcement layer 12 is provided as a single layer or plural layers (by one layer in the example of FIG. 2A and by four layers in the example of FIG. 2B), and performs the role of securing the pressure resistance properties of the hose 1. The reinforcement layer 12 is formed by wrapping a reinforcement material such as fiber, metal wire, or the like onto the outer peripheral surface of the inner tube rubber layer 11, or further to the outside periphery thereof, in a form such as a spiral or braided form (a braided form in the example of FIG. 2A and a spiral form in the example of FIG. 2B).

The outer cover layer 13 forms the outermost layer of the hose 1, and is formed from a substance having friction resistance properties, weather resistance properties, and the like, and is able to protect the hose 1 from the external environment. The substance of the outer cover layer 13 is not particularly limited and may, for example, be formed from a rubber.

Moreover as illustrated in FIG. 2B, a middle rubber layer 14 configured from a single layer or plural layers (3 layers in the example of FIG. 2B) may be disposed between the inner tube rubber layer 11 and the outer cover layer 13.

Next explanation first follows regarding the route to obtaining the hose remaining service life prediction method of the present exemplary embodiment and the hose remaining service life prediction system of the present exemplary embodiment.

In the hose 1 such as described above and illustrated in FIG. 1, the inner tube rubber layer 11 gradually deteriorates even when employed within a range determined by the specification of the hose 1. As a result of diligent research into the causes of deterioration of the inner tube rubber layer 11, the present inventors have discovered that the inner tube rubber layer 11 of the hose 1 deteriorates due to being affected by an additive contained in the fluid for use. The present inventors found that the remaining service life of the hose 1 is predictable by using a same type (same) fluid to the additive-containing fluid that contacts the inner tube rubber layer 11 of the in-service hose 1. The present exemplary embodiment has been conceived based such thinking. Note that sometimes a degree of deterioration with time of the inner tube rubber layer 11 is changed as affected by an additive.

The fluid employed on the machinery 3 of the present exemplary embodiment is, as an example, an oil used in hydraulic machinery, however it may be a fluid other than an oil. An antioxidant may be given as an example of an additive, however the additive may be something other than an antioxidant. Examples that may be given as the antioxidant include a chain stopper, a peroxide decomposer, a metal deactivator, and the like.

### Hose Remaining Service Life Prediction Method

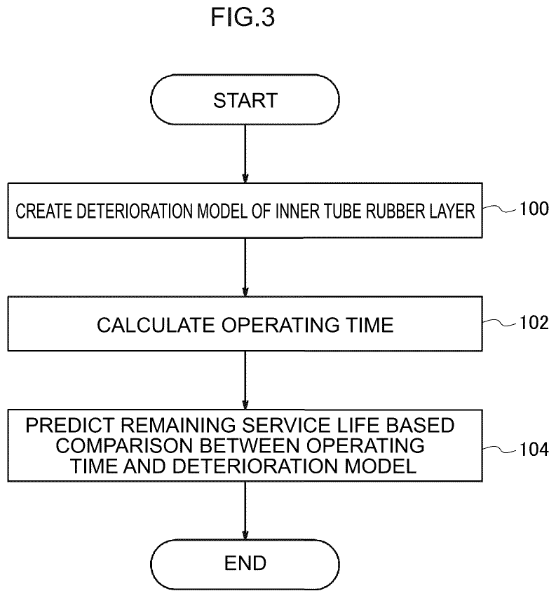

First explanation follows regarding a hose remaining service life prediction method according to an exemplary embodiment of the present disclosure, with reference to FIG. 3 to FIG. 5.

The hose remaining service life prediction method according to the present exemplary embodiment is performed to predict the remaining service life of an in-service hose 1 including at least an inner tube rubber layer 11, a reinforcement layer 12 disposed further to an outside periphery than the inner tube rubber layer 11, and an outer cover layer 13 disposed further to the outside periphery than the reinforcement layer 12.

Although the in-service hose 1 may be freely determined according to on operating mode of machinery, the in-service hose 1 in the present exemplary embodiment is in a state employed while installed to the machinery 3.

As illustrated in FIG. 3, the hose remaining service life prediction method according to the present exemplary embodiment is performed to predict the remaining service life of the in-service hose 1 by finding in advance, for a hose (omitted in the drawings) of the same type to the in-service hose 1, a relationship of an inner tube rubber layer between operating time and a physical property value of rubber configuring the inner tube rubber layer, by creating an inner tube rubber layer deterioration model (step 100: deterioration model creation process), by calculating for the in-service hose 1 an operating time of the inner tube rubber layer 11 up to the prediction time (step 102: operating time calculation process), and by predicting the remaining service life for the in-service hose 1 based on a comparison between the operating time calculated in the operating time calculation process and the deterioration model created in the deterioration model creation process (step 104: remaining service life prediction process).

### Deterioration Model Creation Process

In the deterioration model creation process, a hose (omitted in the drawings; in other words a hose for deterioration model creation) is prepared in advance that is of the same type to the in-service hose 1 (in other words a hose installed and used on the machinery), for this hose a relationship of the inner tube rubber is found between the operating time and the physical property value of the rubber configuring the inner tube rubber layer, and a deterioration model of the inner tube rubber layer is created.

Reference to a hose of the same type to the in-service hose 1 (sometimes simply referred to below as the “same type hose”) indicates a hose in which the rubber configuring the inner tube rubber layer is the same type as that of the in-service hose 1. Note that reference to the rubber being the same type indicates that a rubber formulation is the same.

There is no particular limitation to the physical property value of the rubber configuring the inner tube rubber layer employed in the inner tube rubber layer deterioration model and, for example, elongation at break, breaking strength, and hardness are preferable examples thereof. This is because these are indicators generally employed as physical property values of rubber and so enable accurate measurement. However, the physical property value of rubber employed in the deterioration model is not limited to these indicators, and also plural indicators may be employed. In the present exemplary embodiment explanation follows regarding an example in which elongation at break is employed.

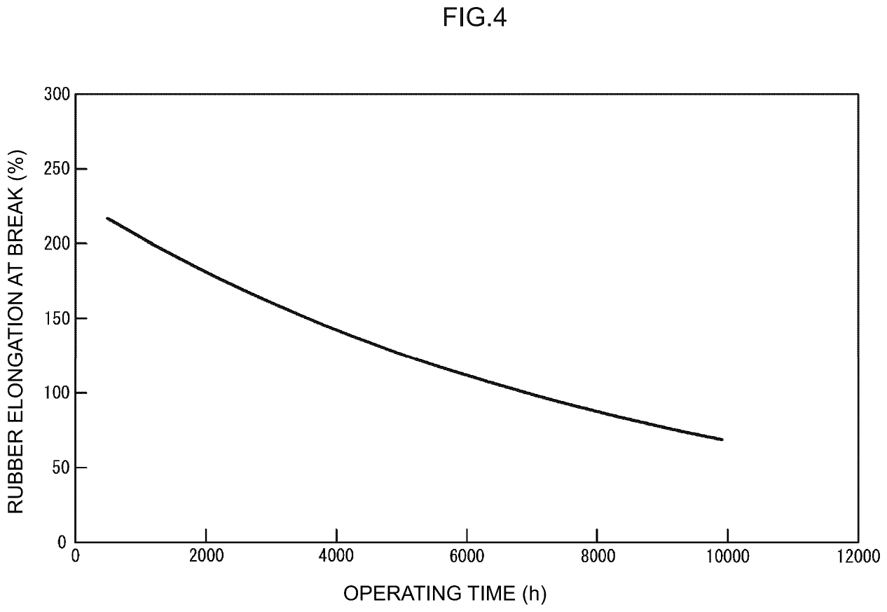

FIG. 4 is a schematic diagram illustrating an example of a deterioration model in the present exemplary embodiment. FIG. 4 illustrates a relationship between operating time (h) of the same type hose, and an elongation at break (%) of the rubber configuring the inner tube rubber layer. In the present exemplary embodiment the deterioration model is, as illustrated in FIG. 4, configured by a graph illustrating the relationship between the operating time and the physical property value of rubber (the elongation at break of rubber in the present example). Hereafter this graph will be called a deterioration curve as appropriate.

The deterioration model may, for example, be configured by a graph indicating a progression in values of the elongation at break of rubber based on results obtained by performing tests of continuously circulating a fluid to which an additive has been added (a same type (same) fluid as the fluid employed in the in-service hose 1) in the same type hose, while measuring the elongation at break of the rubber configuring the inner tube rubber layer for plural operating times.

Note that measurement of the elongation at break of rubber may, for example, be performed using tensile testing based on JIS K6251. Moreover, measurement may, for example, be performed by tests based on JIS K6251 when the breaking strength of rubber is employed as the rubber physical property value, and measurement may, for example, be performed by tests based on JIS K6253 when the rubber hardness is employed therefor.

Note that a deterioration model is created for each of physical property value when plural indicators from out of the elongation at break, breaking strength, and hardness are employed as the rubber physical property value.

### Operating Time Calculation Process

In the operating time calculation process, an operating time is calculated for the in-service hose 1 from a start of use of the inner tube rubber layer 11 up to the time when prediction is made.

The operating time calculation process finds, for example, a cumulative time of the inner tube rubber layer 11 from when the in-service hose 1 was installed on the machinery 3 and started to be used up to the prediction time.

### Remaining Service Life Prediction Process

In the remaining service life prediction process, the remaining service life of the in-service hose 1 is predicted based on a comparison between the operating time calculated in the operating time calculation process and the deterioration model created in the deterioration model creation process.

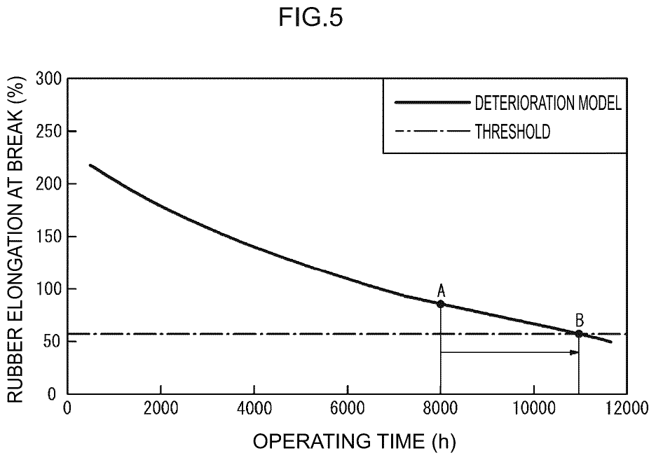

More specifically this may be performed, for example as illustrated in FIG. 5, by setting a threshold for the physical property value of the rubber configuring the inner tube rubber layer 11 as a usage limit for the inner tube rubber layer 11, and predicting a duration from an operating time elapsed time (point A) up to an operating time elapsed time when the physical property value will attain the threshold (point B) in the deterioration model as the remaining service life.

The above method enables the remaining service life of the hose to be predicted both simply and accurately.

The method of setting the threshold of the rubber physical property value is not particularly limited and, for example, the physical property value may be measured for a defective product of the same type hose as that of the in-service hose, and the threshold set based on this value.

Note that when setting the threshold for the rubber physical property value, preferably a value prior to reaching the actual usage limit of the inner tube rubber layer 11 is set so as to enable the in-service hose 1 to be replaced at a stage prior to a defect occurring, such as a fluid leakage, burst hose, or the like.

In the remaining service life prediction process, for example as illustrated in FIG. 5, the operating time may be plotted on the deterioration model, and the elongation at break of the rubber configuring the inner tube rubber layer 11 of the in-service hose 1 estimated at the operating time elapsed time (A). Then a duration from the operating time elapsed time (A) up to the operating time elapsed time (B) when the physical property value will attain the threshold may be predicted as the remaining service life of the in-service hose 1. Note that estimating the elongation at break value of rubber at the point in time of the operating time elapsed time (A) is not always necessary when predicting the remaining service life, as long as the duration until the operating time elapsed time (B) from the operating time elapsed time (A) is known.

The hose remaining service life prediction method of the present exemplary embodiment enables the remaining service life of the hose to be simply predicted for an in-service hose 1 provided with the inner tube rubber layer 11 affected by the additive contained in the fluid merely by obtaining the operating time (cumulative operating time) on the machinery 3 without needing to monitor the pressure or the like.

### Hose Remaining Service Life Prediction System According to the Present Exemplary Embodiment

Next, description follows regarding the hose remaining service life prediction system 100 according to an exemplary embodiment of the present disclosure.

### System Configuration

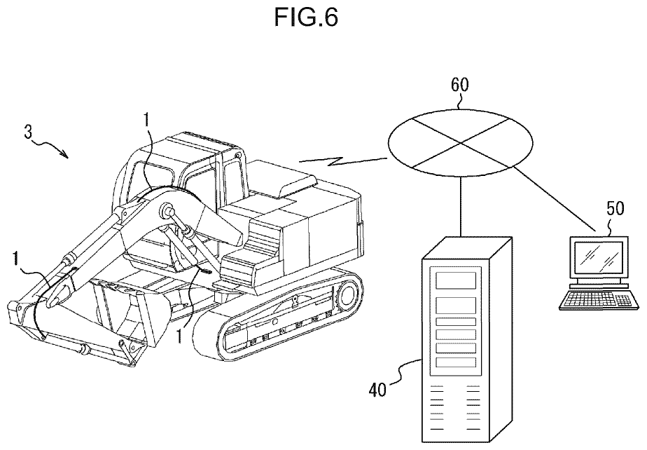

FIG. 6 is a configuration diagram of the hose remaining service life prediction system 100 according to an exemplary embodiment of the present disclosure. In the description of the remaining service life prediction system 100 according to the present exemplary embodiment, “user” means a person who operates a terminal to check the remaining service life of the hose 1 and is, for example, a user of the machinery 3 (for example a construction machine, factory equipment, or the like) installed with the hose 1, a vendor of the machinery 3, a vendor of the hose 1, or the like.

The remaining service life prediction system 100 of the hose 1 is configured including the machinery 3 (a construction machine in the illustrated example) installed with the hose 1, a server 40, and one or more terminal 50. The server 40 is connected over a network 60 so as to be able to communicate respectively with the machinery 3 and the one or more terminal 50.

The machinery 3 transmits data such as operating time to the server 40. A wireless connection or a satellite line are examples of the network 60 for connecting the machinery 3 and the server 40 together.

The server 40 is a server that predicts a remaining service life of the hose 1 based on data received from the machinery 3 and based on data stored in a database, and transmits the prediction to the terminal 50.

Various devices such as a PC, PDA, mobile phone, or the like may be used as examples of the terminal 50.

Moreover, the server 40 and the terminal 50 may belong to different users, or alternatively may be integrated together.

Note that an interface between the server 40 and the terminal 50 may, for example, be implemented by the server 40 launching a WEB server, by providing a WEB browser to the terminal 50, and by using HTTP or HTTPS communication.

### Machinery

The machinery 3 is configured so as to wirelessly transmit to the server 40 operating time data of the inner tube rubber layer 11 for the in-service hose 1 up to the prediction time.

As illustrated in FIG. 6 and FIG. 7, the machinery 3 includes an operating time measurement section 31 (clock or the like) configured from a recording instrument or the like that measures and records operating time of the inner tube rubber layer 11, and an information communication section 32 for transmitting the operating time. Note that such equipment are merely examples thereof, and the machinery 3 may be provided with any freely selected device as the operating time measurement section.

### Server

As illustrated in FIG. 7, the server 40 includes a database 41, a deterioration model creation section 42, an operating time calculation section 43, a remaining service life prediction section 44, and an information communication section 45.

The database 41 is stored with various information employed to predict the remaining service life of the hose 1. The database 41 is able to receive information from the deterioration model creation section 42.

The operating time calculation section 43 calculates an operating time up to the prediction time for the in-service hose 1.

The operating time calculation section 43 preferably includes a data acquisition section (omitted in the drawings; for example a terminal with a receiver attached) to acquire time data up to the prediction time of the inner tube rubber layer 11 for the in-service hose 1.

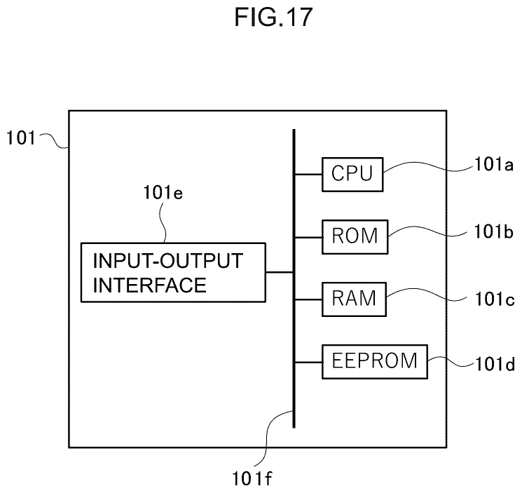

As illustrated in FIG. 17, the hardware of the server 40 includes, for example, a CPU 101a serving as a processor, ROM 101b serving as memory, RAM 101c, EEPROM 101d, an input-output interface 101e, and the like. The ROM 101b, the RAM 101c, the EEPROM 101d, the input-output interface 101e, and the like are configured so as to be able exchange data with the CPU 101a through an internal bus 101f.

The CPU 101a functions as the deterioration model creation section 42 by performing the processing of the deterioration model creation process, the CPU 101a functions as the operating time calculation section 43 by performing the processing of the operating time calculation process, and the CPU 101a functions as the remaining service life prediction section 44 by performing the processing of the remaining service life prediction process.

Note that at least one out of the deterioration model creation section 42, the operating time calculation section 43, and the remaining service life prediction section 44 may be a device.

As illustrated in FIG. 7, the information communication section 45 transmits the predicted remaining service life of the in-service hose 1 to the terminal 50. The information communication section 45 is employed for the server 40 to perform communication with the machinery 3 and the terminal 50 over the network 60. Note that the components of the server 40 may be incorporated into the machinery 3. Moreover, the terminal 50 may also be incorporated into the machinery 3.

### Deterioration Model Creation Section

The deterioration model creation section 42 is able to create information used in predicting the remaining service life of the hose 1 and to transmit the information to the database 41. The deterioration model creation section 42 finds, for a hose of the same type to the in-service hose 1, a relationship of the inner tube rubber layer between an operating time and a physical property value of the rubber configuring the inner tube rubber layer, and creates a deterioration model for the inner tube rubber layer.

There are no particular limitations to the physical property value of the rubber configuring the inner tube rubber layer used in the inner tube rubber layer deterioration model and, for example, elongation at break, breaking strength, and hardness are preferably employed therefor. This is because these are indicators generally employed as physical property values of rubber and so enable accurate measurement. However, the physical property value of rubber employed in the deterioration model is not limited to these indicators, and plural indicators may be employed. In the present exemplary embodiment explanation follows regarding an example in which elongation at break is employed.

Moreover in the present exemplary embodiment, an example of the deterioration model is a graph representing a relationship between operating time and a physical property value of rubber (the elongation at break of rubber in the present example) such as illustrated in FIG. 4 as described above.

Note that a deterioration model is created for each physical property value in cases in which plural indicators from out of elongation at break, breaking strength, and hardness are employed as the physical property value of rubber.

### Operating Time Calculation Section

The operating time calculation section 43 calculates (obtains) for the in-service hose 1 a cumulative operating time of the inner tube rubber layer 11 from start of use to the prediction time.

The operating time calculation section 43 (data acquisition section) preferably acquires data transmitted from the machinery 3 over the network 60.

### Remaining Service Life Prediction Section

The remaining service life prediction section 44 predicts the remaining service life of the in-service hose 1 based on a comparison between the operating time of the inner tube rubber layer 11 as calculated by the operating time calculation section 43, and the deterioration model stored in the database 41 as created by the deterioration model creation section 42 and stored in the database 41.

More specifically, for example as illustrated in FIG. 5, a threshold of the physical property value of the rubber configuring the inner tube rubber layer 11 is set as a usage limit for the inner tube rubber layer 11, and the remaining service life of the hose can be predicted more simply and accurately due to being able to predict a duration from the operating time elapsed time (point A) up to the operating time elapsed time (point B) when the physical property value will attain the threshold in the deterioration model as the remaining service life.

Note that setting of the threshold may be performed by setting in advance in the remaining service life prediction section 44, and may be performed by being input or changed manually by a user or the like. In other words, a threshold setting section may be provided to the remaining service life prediction section 44, or may be provided independently of the remaining service life prediction section 44.

The method of setting the threshold of the physical property value of rubber is not particularly limited and, for example, a physical property value of a defective product of a hose of the same type to as the in-service hose 1 may be measured, and the threshold set based on this value.

Note that when setting the threshold for the rubber physical property value, preferably a value prior to reaching the actual usage limit of the inner tube rubber layer 11 is set so as to enable the hose 1 to be replaced at a stage prior to a defect occurring in the hose 1.

The remaining service life prediction section may, for example similarly to in the remaining service life prediction process described above, be configured so as to plot the operating time on the deterioration model as illustrated in FIG. 5, and to estimate the elongation at break of the rubber configuring the inner tube rubber layer 11 of the hose 1 at the operating time elapsed time (A).

Note that in the deterioration model and in setting the threshold, from out of plural indicators preferably an indicator of the physical property value that deteriorates the fastest is employed.

### Terminal

The terminal 50 receives the remaining service life of the hose 1 that was predicted by the remaining service life prediction section 44, and is able, for example, to display the remaining service life of the hose 1 on a display screen.

The hose remaining service life prediction system of the present exemplary embodiment enables the remaining service life to be simply predicted for the in-service hose 1 provided with the inner tube rubber layer 11 affected by the additive contained in the fluid merely by obtaining the operating time (cumulative operating time) on the machinery 3, without needing to monitor the pressure or the like.

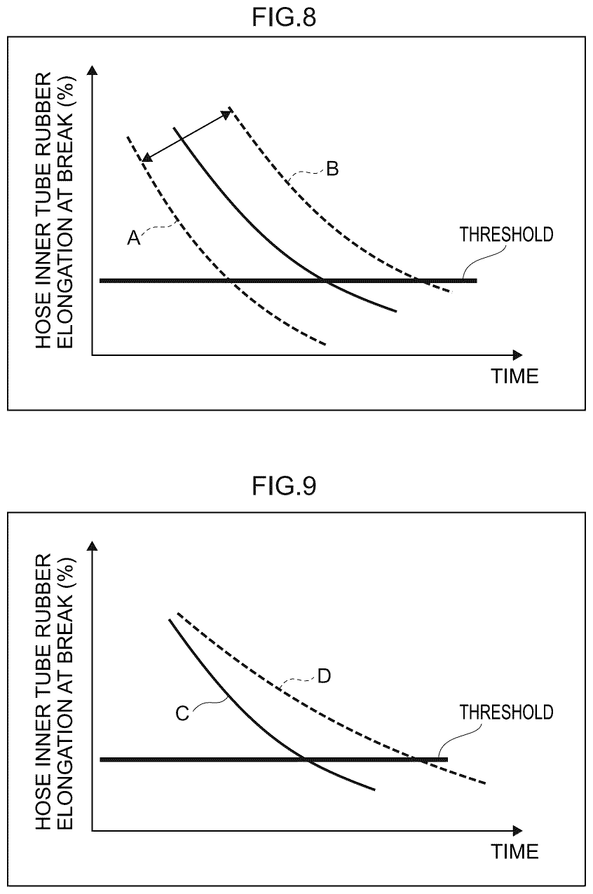

Note that as illustrated in FIG. 8, the deterioration model (deterioration curve) changes according to the type of additive. For example, the deterioration curve A is for a case in which an additive that readily causes deterioration of rubber was employed, and the deterioration curve B is for a case in which an additive that is not liable to cause deterioration of rubber was employed.

Moreover, sometimes rubber deteriorates and has a short service life due to high temperatures. For example, there are sometimes cases in which fluid flows at high temperature through the hose 1 due to using the machinery 3 continuously. The rubber is heated by the high temperature fluid contacting the rubber, and sometimes this promotes deterioration of the rubber.

Thus in cases in which an operation mode is one such as this in which deterioration of rubber is promoted by temperature, preferably the deterioration model is generated employing fluid at a temperature similar to that in the in-service hose 1.

### Supplement 1

A hose remaining service life prediction method to predict a remaining service life of an in-service hose at least including an inner tube rubber layer configured containing rubber having an inside portion contacted by a fluid to which an additive has been added and for which a change with time of a physical property value is affected by the additive and including a reinforcement layer disposed further to an outside periphery than the inner tube rubber layer. The hose remaining service life prediction method includes a deterioration model creation process that, for a hose of the same type to the in-service hose, uses the fluid to find a relationship of the inner tube rubber layer between an operating time and the physical property value of the rubber and to create a deterioration model of the inner tube rubber layer, includes an operating time calculation process that for the in-service hose calculates an operating time of the inner tube rubber layer from start of use up to when the prediction is performed, and includes a remaining service life prediction process that predicts the remaining service life of the in-service hose based on the operating time calculated in the operating time calculation process and on the deterioration model created in the deterioration model creation process.

### Supplement 2

A hose remaining service life prediction system to predict a remaining service life of an in-service hose at least including an inner tube rubber layer configured containing rubber having an inside portion contacted by a fluid to which an additive has been added and for which a change with time of a physical property value is affected by the additive and including a reinforcement layer disposed further to an outside periphery than the inner tube rubber layer. The hose remaining service life prediction system includes a deterioration model creation section that for a hose of the same type to the in-service hose uses the fluid to find a relationship of the inner tube rubber layer between an operating time and the physical property value of the rubber and to create a deterioration model of the inner tube rubber layer, includes an operating time calculation section that for the in-service hose calculates an operating time of the inner tube rubber layer from start of use up to when the prediction is performed, and includes a remaining service life prediction section that predicts the remaining service life of the in-service hose based on the operating time calculated by the operating time calculation section and on the deterioration model created by the deterioration model creation section.

### Second Exemplary Embodiment

Next, description follows regarding a hose remaining service life prediction method and a hose remaining service life prediction system according to a second exemplary embodiment. Note that the same reference numerals will be appended to the same configuration to the previously described exemplary embodiment, and explanation thereof will be omitted.

The second exemplary embodiment is one in which service life prediction is performed for a hose 1 in a case in which the physical property of an inner tube rubber layer 11 changes according to a physical property of the fluid itself.

### Hose Remaining Service Life Prediction Method According to Second Exemplary Embodiment

The present inventors have, as a result of diligent research into operation modes of hose and causes of deterioration of the inner tube rubber layer 11, discovered that there are sometimes cases in which a fluid without any additional additive is used on the machinery 3, and as an example have discovered that the inner tube rubber layer 11 has a physical property value that changes with time as affected by the physical property of the fluid for use itself, giving rise to timewise deterioration. The present inventors have found that the remaining service life of the hose 1 is predictable by using a same type (same) fluid to the fluid contacting the inner tube rubber layer 11 of the in-service hose 1. The second exemplary embodiment is based on such thinking.

Note that there are sometimes cases in which the inner tube rubber layer 11 exhibits a degree of timewise change (timewise deterioration) due to being affected by the fluid itself.

Note that in the second exemplary embodiment the same reference numerals will be appended to the same configuration to that of the previously described exemplary embodiment, and explanation thereof will be omitted. Note also that similarly to the hose 1 of the first exemplary embodiment, the hose 1 of the second exemplary embodiment is installed to and used on the machinery 3.

In the hose remaining service life prediction method according to the second exemplary embodiment, a remaining service life of an in-service hose 1 is predicted by performing processing of using a same type (same) fluid to the fluid contacting the inner tube rubber layer 11 of the in-service hose 1 for a hose of the same type to the in-service hose 1 to find in advance a relationship of the inner tube rubber layer between the operating time and a physical property value of the rubber configuring the inner tube rubber layer and to create a deterioration model of the inner tube rubber layer (deterioration model creation process), calculating for the in-service hose 1 an operating time of the inner tube rubber layer 11 up to the prediction time (operating time calculation process), and predicting the remaining service life of the in-service hose 1 based on a comparison between the operating time as calculated in the operating time calculation process and the deterioration model as created in the deterioration model creation process (remaining service life prediction process) (similar to in the exemplary embodiment described above; see FIG. 3).

### Deterioration Model Creation Process

Similarly to in the exemplary embodiment described above, in the deterioration model creation process, a hose of the same type to the in-service hose 1 is prepared in advance, and for this hose a relationship of the inner tube rubber between the operating time and the physical property value of the rubber configuring the inner tube rubber layer is found and a deterioration model of the inner tube rubber layer is created.

Similarly to in the exemplary embodiment described above, the deterioration model may, for example, be configured by a graph indicating a progression in values of the elongation at break of rubber based on results obtained by performing tests of continuously circulating a fluid (a same type (same) fluid to that of the in-service hose 1) in the same type hose while measuring the elongation at break of the rubber configuring the inner tube rubber layer for plural operating times.

### Operating Time Calculation Process

Similarly to in the exemplary embodiment described above, the operating time calculation process finds, for example, a cumulative time for the in-service hose 1 of the inner tube rubber layer 11 from start of use up to the prediction time.

### Remaining Service Life Prediction Process

Similarly to in the exemplary embodiment described above, in the remaining service life prediction process, the remaining service life of the in-service hose 1 is predicted based on a comparison between the operating time calculated in the operating time calculation process and the deterioration model created in the deterioration model creation process (similar to in the exemplary embodiment described above; see FIG. 6).

The hose remaining service life prediction method of the second exemplary embodiment enables, for the in-service hose 1 provided with the inner tube rubber layer 11 affected by the physical property of the fluid, simple prediction of the remaining service life of the hose merely by obtaining the operating time (cumulative operating time) on the machinery 3, without needing to monitor the pressure or the like.

### Hose Remaining Service Life Prediction System According to Second Exemplary Embodiment

Next description follows regarding a hose remaining service life prediction system according to the second exemplary embodiment. The hose remaining service life prediction system according to the second exemplary embodiment employs a similar device configuration (hardware) to that of the exemplary embodiment described above and so description of the device configuration will be omitted, and only points of difference will be described.

A deterioration model creation section 42 of the remaining service life prediction system 100 of the second exemplary embodiment uses a hose of the same type to the in-service hose 1 and a fluid with no additional additive used in the hose 1 to find a relationship of the inner tube rubber layer between the operating time and the physical property value of the rubber configuring the inner tube rubber layer, and to create a deterioration model of the inner tube rubber layer.

Thereby in the hose remaining service life prediction system 100 according to the second exemplary embodiment, the hose remaining service life can be simply predicted for the in-service hose 1 provided with the inner tube rubber layer 11 affected by the physical property of the fluid merely by obtaining the operating time (cumulative operating time) on the machinery 3, without needing to monitor the pressure or the like.

Note that in cases in which the fluid is an oil, the rubber of the inner tube rubber layer 11 sometimes becomes more liable to swell and stretch due to being contacted by the oil, and so as a result thereof sometimes the elongation at break is increased and the service life is extended as the hose 1.

Moreover, the rubber becomes more liable to swell and the rubber becomes more liable to stretch when an oil with a low aniline point is employed, and so a deterioration (for example, a worsening of elongation at break) is suppressed, and the hose 1 used with an oil with a low aniline point has a service life that is extended compared to cases in which an oil with a high aniline point is employed.

In FIG. 9 illustrates, as an example, a deterioration curve C when used with an oil with a high aniline point, and a deterioration curve D when used with an oil with a low aniline point.

### Supplement 3

A hose remaining service life prediction method to predict a remaining service life of an in-service hose at least including an inner tube rubber layer configured containing rubber having an inside portion contacted by a fluid and for which a change with time of a physical property value is affected by a physical property of the fluid, including a reinforcement layer disposed further to an outside periphery than the inner tube rubber layer, and including an outer cover layer disposed further to the outside periphery than the reinforcement layer. The hose remaining service life prediction method includes a deterioration model creation process that, for a hose of the same type to the in-service hose, uses the fluid to find in advance a relationship of the inner tube rubber layer between an operating time and the physical property value of the rubber and to create a deterioration model of the inner tube rubber layer, includes an operating time calculation process that for the in-service hose calculates an operating time of the inner tube rubber layer from start of use up to when the prediction is performed, and includes a remaining service life prediction process that predicts the remaining service life of the in-service hose based on the operating time calculated in the operating time calculation process and on the deterioration model created in the deterioration model creation process.

### Supplement 4

A hose remaining service life prediction system to predict a remaining service life of an in-service hose at least including an inner tube rubber layer configured containing rubber having an inside portion contacted by a fluid and for which a change with time of a physical property value is affected by a physical property of the fluid, including a reinforcement layer disposed further to an outside periphery than the inner tube rubber layer, and including an outer cover layer disposed further to the outside periphery than the reinforcement layer. The hose remaining service life prediction system includes a deterioration model creation section that, for a hose of the same type to the in-service hose, uses the fluid to find a relationship of the inner tube rubber layer between an operating time and the physical property value of the rubber and to create a deterioration model of the inner tube rubber layer, includes an operating time calculation section that for the in-service hose calculates an operating time of the inner tube rubber layer from start of use up to when the prediction is performed, and includes a remaining service life prediction section that predicts the remaining service life of the in-service hose based on the operating time calculated by the operating time calculation section and on the deterioration model created by the deterioration model creation section.

### Third Exemplary Embodiment

Next, description follows regarding a hose remaining service life prediction method and a hose remaining service life prediction system according to a third exemplary embodiment. Note that the same reference numerals will be appended to the same configuration to that of the previously described exemplary embodiments, and explanation thereof will be omitted.

The third exemplary embodiment performs service life prediction of a hose 1 in which an inner tube rubber layer 11 deteriorates by deterioration of a fluid.

### Hose Remaining Service Life Prediction Method of Third Exemplary Embodiment

The present inventors have, as a result of diligent research into operation modes of hoses and causes of deterioration of the inner tube rubber layer 11, found that there are sometimes cases in which a fluid that has deteriorated continues to be used on the machinery 3, and as an example have discovered that the inner tube rubber layer 11 has a physical property value that changes with time as affected by the deteriorated fluid, giving rise to timewise deterioration of the inner tube rubber layer 11. The present inventors have found that the remaining service life of the hose 1 is predictable by using a same type (same) fluid to the fluid contacting the inner tube rubber layer 11 of the in-service hose 1. The third exemplary embodiment is configured based on this thinking. Note that the inner tube rubber layer 11 sometimes exhibits a degree of deterioration with time (timewise deterioration) that changes as affected by the deteriorated fluid.

Note that in the third exemplary embodiment the same reference numerals will be appended to the same configuration to that of the previously described exemplary embodiments, and explanation thereof will be omitted. Note also that similarly to the hose 1 of the first exemplary embodiment, the hose 1 of the third exemplary embodiment is installed to and used on the machinery 3.

In the hose remaining service life prediction method according to the third exemplary embodiment a remaining service life of an in-service hose 1 is predicted by performing processing of finding in advance, for a same type (same) a hose of the same type to the in-service hose 1, a relationship of the inner tube rubber layer between the operating time and a physical property value of the rubber configuring the inner tube rubber layer and creating a deterioration model of the inner tube rubber layer (deterioration model creation process), of calculating for the in-service hose 1 an operating time of the inner tube rubber layer 11 up to the prediction time (operating time calculation process), and of predicting the remaining service life of the in-service hose 1 based on a comparison between the operating time as calculated in the operating time calculation process and the deterioration model as created in the deterioration model creation process (remaining service life prediction process) (similar to in the exemplary embodiment illustrated in FIG. 3).

### Deterioration Model Creation Process

Similarly to in the exemplary embodiment described above, in the deterioration model creation process a hose of the same type to the in-service hose 1 (in other words to the hose installed to and being used on machinery or the like) is prepared in advance, and for this hose a relationship of the inner tube rubber is found between the operating time and the physical property value of the rubber configuring the inner tube rubber layer and a deterioration model of the inner tube rubber layer is created.

Similarly to in the exemplary embodiment described above, the deterioration model may, for example, be a graph indicating a progression in values of the elongation at break of rubber based on results obtained by performing tests of continuously circulating a fluid (a deteriorated fluid of the same type (same) to that of the in-service hose 1) in the same type hose while measuring the elongation at break of the rubber configuring the inner tube rubber layer for plural operating times.

### Operating Time Calculation Process

Similarly to in the exemplary embodiment described above, the operating time calculation process finds, for example, a cumulative time for the in-service hose 1 from start of use of the inner tube rubber layer 11 up to the prediction time.

### Remaining Service Life Prediction Process

Similarly to in the exemplary embodiment described above, the remaining service life prediction process predicts the remaining service life of the in-service hose 1 based on a comparison between the operating time as calculated in the operating time calculation process and the deterioration model as created in the deterioration model creation process.

More specifically this processing may be performed by, for example as illustrated in FIG. 5, setting a threshold of the physical property value of rubber configuring the inner tube rubber layer 11 as a usage limit of the inner tube rubber layer 11, and predicting a duration in the deterioration model from an operating time elapsed time up to an operating time elapsed time when the physical property value will be the threshold as the remaining service life.

The hose remaining service life prediction method of the third exemplary embodiment is able to simply predict the remaining service life of hose for the in-service hose 1 provided with the inner tube rubber layer 11 affected by deterioration of the fluid merely by obtaining the operating time (cumulative operating time) on the machinery 3, without needing to monitor the pressure or the like.

Hose Remaining Service Life Prediction System According to Third Exemplary Embodiment

Next, description follows regarding the hose remaining service life prediction system according to the third exemplary embodiment. The hose remaining service life prediction system according to the third exemplary embodiment includes a similar device configuration (hardware) to that of the exemplary embodiments described above and so description of the device configuration will be omitted, and only points of difference will be described.

In a deterioration model creation section 42 of the remaining service life prediction system of the third exemplary embodiment, a hose of the same type to the in-service hose 1 and a fluid used in this hose 1 is employed to find a relationship of the inner tube rubber layer between the operating time and a physical property value of the rubber configuring the inner tube rubber layer and to create a deterioration model of the inner tube rubber layer.

Thus the hose remaining service life prediction system according to the third exemplary embodiment enables the remaining service life of a hose to be simply predicted for the in-service hose 1 provided with the inner tube rubber layer 11 affected by the physical property of the fluid merely by obtaining the operating time (cumulative operating time) on the machinery 3, without needing to monitor the pressure or the like.

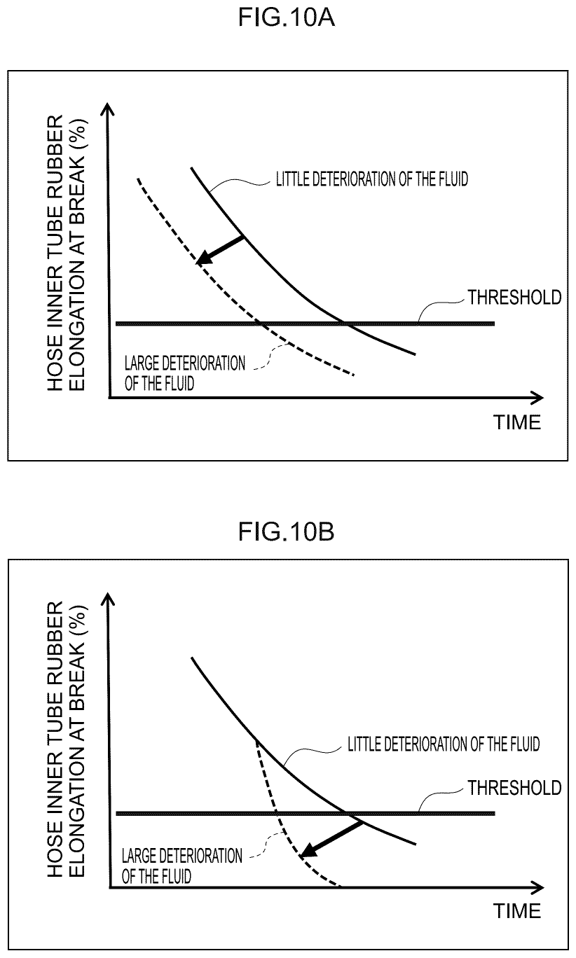

Note that FIG. 10A and FIG. 10B illustrate, as an example, examples of a deterioration curve for a case in which there is a little deterioration of the fluid, and a deterioration curve for a case in which there is a large deterioration of the fluid.

### Supplement 5

A hose remaining service life prediction method to predict a remaining service life of an in-service hose at least including an inner tube rubber layer configured containing rubber having an inside portion contacted by a fluid that deteriorates with time and for which a change with time of a physical property value is affected by deterioration of the fluid, including a reinforcement layer disposed further to an outside periphery than the inner tube rubber layer, and including an outer cover layer disposed further to the outside periphery than the reinforcement layer. The hose remaining service life prediction method includes a deterioration model creation process that, for a hose of the same type to the in-service hose, uses the fluid to find a relationship of the inner tube rubber layer between an operating time and the physical property value of the rubber and to create a deterioration model of the inner tube rubber layer, includes an operating time calculation process that for the in-service hose calculates an operating time of the inner tube rubber layer from start of use up to when the prediction is performed, and includes a remaining service life prediction process that predicts the remaining service life of the in-service hose based on the operating time calculated in the operating time calculation process and on the deterioration model created in the deterioration model creation process.

### Supplement 6

A hose remaining service life prediction system to predict a remaining service life of an in-service hose at least including an inner tube rubber layer configured containing rubber having an inside portion through which a fluid that deteriorates with time passes and for which a change with time of a physical property value is affected by deterioration of the fluid, including a reinforcement layer disposed further to an outside periphery than the inner tube rubber layer, and including an outer cover layer disposed further to the outside periphery than the reinforcement layer. The hose remaining service life prediction system includes a deterioration model creation section that, for a hose of the same type to the in-service hose, uses the fluid to find a relationship of the inner tube rubber layer between an operating time and the physical property value of the rubber and to create a deterioration model of the inner tube rubber layer, includes an operating time calculation section that for the in-service hose calculates an operating time of the inner tube rubber layer from start of use up to when the prediction is performed, and includes a remaining service life prediction section that predicts the remaining service life of the in-service hose based on the operating time calculated by the operating time calculation section and on the deterioration model created by the deterioration model creation section.

### Fourth Exemplary Embodiment

Next, description follows regarding a hose remaining service life prediction method and a hose remaining service life prediction system according to a fourth exemplary embodiment. Note that the same reference numerals will be appended to the same configuration to that of the previously described exemplary embodiments, and explanation thereof will be omitted.

The fourth exemplary embodiment is an embodiment in which the threshold is changed according to a hose operation mode (degree of strain; degree of bending as an example).

### Hose Remaining Service Life Prediction Method and Hose Remaining Service Life Prediction System According to Fourth Exemplary Embodiment

In general rubbers, when a rubber in which a high tensile force (tensile strain) acts is compared against a rubber in which a low tensile force acts (or no tensile force acts), the rubber in which a high tensile force acts tends to be more liable a malfunction (for example cracks developing, cracks propagating, or the like) occurring.

Namely, the service life can be said to be shorter for a rubber in which a high tensile force (tensile strain) acts than in a rubber in which a low tensile force acts (or no tensile force acts).

As an example of the hose 1, there are cases in which, as illustrated in FIG. 11A, the hose 1 is used while fixed in a state having a comparatively large radius of curvature R (in other words, the hose 1 is only slightly bent (including a straight line shape), and there are cases in which, as illustrated in FIG. 11B, the hose 1 is fixed and used in a state having a comparatively small radius of curvature R (in other words is bent greatly), the hose 1 of the latter case (FIG. 11B) has a greater strain acting in the rubber than the hose 1 of the former (FIG. 11A).

The service life can accordingly be said to be shorter for the rubber with the large strain even when the physical property (elongation at break) of the rubber is the same.

When the hose 1 is deformed by bending, the rubber on the curvature radial outside portion is tensioned (the rubber on the curvature radial inside portion is compressed), and tensile strain arises. The smaller the curvature radius of the hose 1 the larger the tensile strain that arises in the rubber of the hose 1.

Thus even in cases in which the same fluid is used, a threshold of the physical property value is preferably changed according to the magnitude of strain arising in the inner tube rubber layer 11 (in particular according to a magnitude of strain under tension when rubber).

Note that the strain referred to here is, as an example, a maximum strain acting in the hose 1.

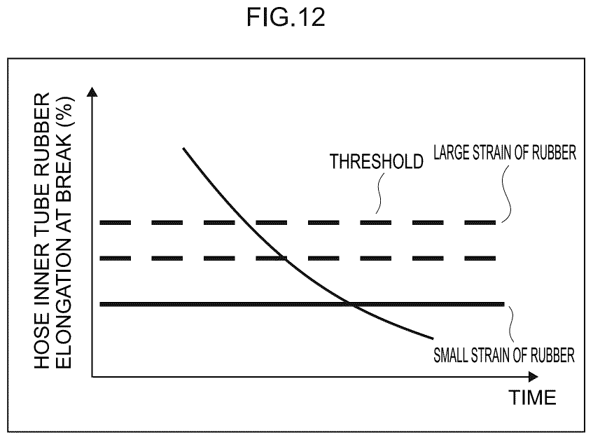

More specifically, as illustrated in FIG. 12, the threshold is shifted upward as the strain increase.

As a shift amount of the threshold, a hose of the same type to the in-service hose 1 is employed and this hose is bent the same as the in-service hose 1 and a bend deterioration model is created therefor. The threshold may be set using an operating time at the point in time when the hose of the deterioration model malfunctions (as an example cracks develop or the like and the fluid leaks) as a usage limit, and this threshold stored in the remaining service life prediction section 44.

### Supplement 7

A hose remaining service life prediction method to predict a remaining service life of an in-service hose at least including an inner tube rubber layer and a reinforcement layer disposed further to an outside periphery than the inner tube rubber layer. The hose remaining service life prediction method includes a deterioration model creation process that in advance, for a hose of the same type and same operation mode to the in-service hose, uses the fluid to find a relationship of the inner tube rubber layer between an operating time and the physical property value of the rubber and to create a deterioration model of the inner tube rubber layer, includes an operating time calculation process that for the in-service hose calculates an operating time of the inner tube rubber layer from start of use up to when the prediction is performed, includes a threshold setting process in which a threshold of the physical property value is set as a usage limit of the inner tube rubber layer according to a magnitude of strain arising in the inner tube rubber layer, and includes a remaining service life prediction process that considers the operating time calculated in the operating time calculation process and the deterioration model created in the deterioration model creation process and predicts a duration from an operating time elapsed time up to an operating time attainment time when the physical property value will attain the threshold in the deterioration model as the remaining service life of the in-service hose.

### Supplement 8

The hose remaining service life prediction method of Supplement 7, wherein the strain is a maximum strain acting in the hose.

### Supplement 9

A hose remaining service life prediction system to predict a remaining service life of an in-service hose at least including an inner tube rubber layer and a reinforcement layer disposed further to an outside periphery than the inner tube rubber layer. The hose remaining service life prediction system includes a deterioration model creation section that, for a hose of the same type and same operation mode to the in-service hose, uses the fluid to find a relationship of the inner tube rubber layer between an operating time and the physical property value of the rubber and to create a deterioration model of the inner tube rubber layer, includes an operating time calculation section that for the in-service hose calculates an operating time of the inner tube rubber layer from start of use up to when the prediction is performed, includes a threshold setting section in which a threshold of the physical property value is set as a usage limit of the inner tube rubber layer according to a magnitude of strain arising in the inner tube rubber layer, and includes a remaining service life prediction section that considers the operating time calculated by the operating time calculation section and the deterioration model created by the deterioration model creation section and predicts a duration from an operating time elapsed time up to an operating time attainment time when the physical property value will attain the threshold in the deterioration model as the remaining service life of the in-service hose.

### Supplement 10

The hose remaining service life prediction system of Supplement 9, wherein the strain is a maximum strain acting in the hose.

### Fifth Exemplary Embodiment

Next, description follows regarding a hose remaining service life prediction method and a hose remaining service life prediction system according to a fifth exemplary embodiment. Note that the same reference numerals will be appended to the same configuration to that of the previously described exemplary embodiments, and explanation thereof will be omitted.

Although in the fifth exemplary embodiment the threshold is changed according to hose operation mode (bending as an example), the operation mode differs from that of Reference Example 3.

### Hose Remaining Service Life Prediction Method and Hose Remaining Service Life Prediction System According to Fifth Exemplary Embodiment

In general rubbers, when a case in which strain acts repeatedly (as an example cases in which strain changes in magnitude) is compared against a case in which strain does not act repeatedly, the rubber in which strain acts repeatedly tends to be more liable to a malfunction (for example cracks developing, cracks propagating, or the like) occurring.

Namely, a rubber in which a large tensile force (tensile strain) acts can be said to have a shorter service life than a rubber in which a small tensile force acts (or no tensile force acts).

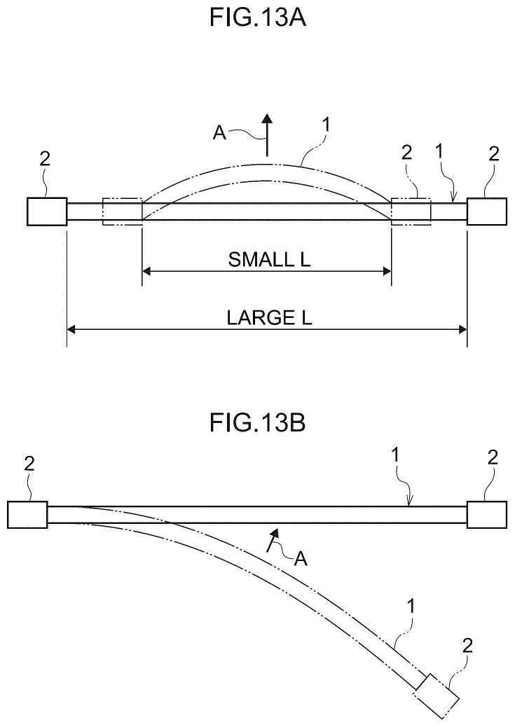

As the hose 1 used in the machinery 3 there are, for example as illustrated in FIG. 13A and FIG. 13B, cases in which a distance L between a length direction one-end portion and other-end portion changes in magnitude so as to become a convex shape in a one-direction as a one side (an arrow A direction indicated in FIG. 13A and FIG. 13B; in other words a one-direction intersecting with the length direction of the hose 1 or a radial direction of the hose 1), and cases in which as an example the distance L between the length direction one-end portion and other-end portion does no change (omitted in the drawings; in other words cases in which the in-service hose 1 does not move), and the former cases can be said to have a shorter service life of rubber than the latter case.

Note that the service life of rubber can be said to be shorter as the amplitude of the hose 1 gets greater and as the number of repetitions increases.

Thus even in cases in which the same fluid is used, preferably the threshold of the physical property value is changed according to the operation mode of the hose 1.

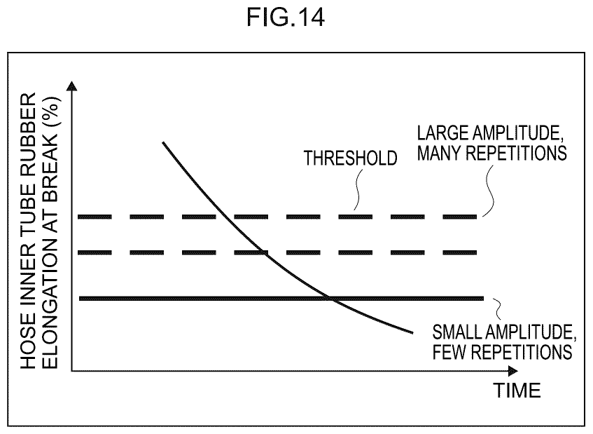

More specifically, the threshold is shifted upward such as illustrated in FIG. 14 as the amplitude of the hose 1 gets greater and as the number of repetitions increases.

As the amount to shift the threshold, the threshold may be set by employing a hose of the same type to the in-service hose 1, creating the deterioration model by moving this hose the same as the in-service hose 1, and taking the operating time at the point in time when the hose of the deterioration model malfunctions (as an example cracks develop and fluid leaks) as the usage limit, and storing this threshold in the remaining service life prediction section 44.

### Supplement 11

A hose remaining service life prediction method to predict a remaining service life of an in-service hose at least including an inner tube rubber layer having an inside portion contacted by a fluid and used with a distance between a length direction one-end portion and other-end portion that changes in magnitude so as to form a convex shape toward a one-direction, and including a reinforcement layer disposed further to an outside periphery than the inner tube rubber layer. The hose remaining service life prediction method includes a deterioration model creation process that in advance, for a hose of the same type and same operation mode to the in-service hose, uses the fluid to find a relationship of the inner tube rubber layer between an operating time and the physical property value of the rubber and to create a deterioration model of the inner tube rubber layer, includes an operating time calculation process that for the in-service hose calculates an operating time of the inner tube rubber layer from start of use up to when the prediction is performed, includes a threshold setting process in which a threshold of the physical property value is set as a usage limit of the inner tube rubber layer according a change amount of the distance of the inner tube rubber layer and a number of repetitions of bending the inner tube rubber layer due to changing the distance, and includes a remaining service life prediction process that considers the operating time calculated in the operating time calculation section and the deterioration model created in the deterioration model creation section and predicts a duration from an operating time elapsed time up to an operating time attainment time when the physical property value will attain the threshold in the deterioration model as the remaining service life of the in-service hose.

### Supplement 12

A hose remaining service life prediction system to predict a remaining service life of an in-service hose at least including an inner tube rubber layer having an inside portion contacted by a fluid and used with a distance between a length direction one-end portion and other-end portion that changes in magnitude so as to form a convex shape toward a one-direction, and including a reinforcement layer disposed further to an outside periphery than the inner tube rubber layer. The hose remaining service life prediction system includes a deterioration model creation section that, for a hose of the same type and same operation mode to the in-service hose, uses the fluid to find a relationship of the inner tube rubber layer between an operating time and the physical property value of the rubber and to create a deterioration model of the inner tube rubber layer, includes an operating time calculation section that for the in-service hose calculates an operating time of the inner tube rubber layer from start of use up to when the prediction is performed, includes a threshold setting section in which a threshold of the physical property value is set as a usage limit of the inner tube rubber layer according a change amount of the distance of the inner tube rubber layer and a number of repetitions of bending the inner tube rubber layer due to changing the distance, and includes a remaining service life prediction section that considers the operating time calculated by the operating time calculation section and the deterioration model created by the deterioration model creation section and predicts a duration from an operating time elapsed time up to an operating time attainment time when the physical property value will attain the threshold in the deterioration model as the remaining service life of the in-service hose.

### Sixth Exemplary Embodiment

Next, description follows regarding a hose remaining service life prediction method and a hose remaining service life prediction system according to a sixth exemplary embodiment. Note that the same reference numerals will be appended to the same configuration to that of the previously described exemplary embodiments, and explanation thereof will be omitted.

In the sixth exemplary embodiment, the threshold is changed according to the operation mode (bending as an example) of the hose, however the operation mode differs to in the Reference Examples 3, 4.

### Hose Remaining Service Life Prediction Method and Hose Remaining Service Life Prediction System of Sixth Exemplary Embodiment

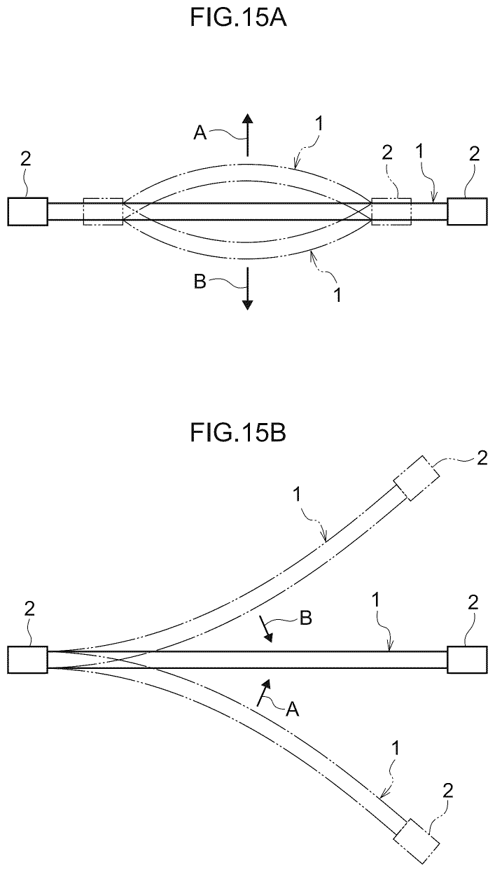

As the hose 1 used in the machinery 3, there are, for example as illustrated in FIG. 15A and FIG. 15B, cases in which as an example the hose 1 is used with a distance between a length direction one-end portion and other-end portion that changes in magnitude such that the hose 1 deforms in a convex shape alternately toward a one-direction side (an arrow A direction indicated in FIG. 15A and FIG. 15B; in other words a one-direction intersecting with the length direction of the hose 1, or one-direction inward in the radial direction of the hose 1) and toward an other-direction side (an arrow B direction indicated in FIG. 15A and FIG. 15B; in other words an other-direction (an opposite direction to the one-direction) intersecting with the length direction of the hose 1, or the other-direction in the radial direction of the hose 1), and as an example cases in which the distance L between the length direction one-end portion and other-end portion does not change (omitted in the drawings; in other words cases in which the in-service hose 1 does not move). Thus the former cases can be said to have a shorter service life of rubber compared to the latter cases.

Note that tension and compression alternately act in the rubber of the inner tube rubber layer 11 in the hose 1 that deforms in a convex shape alternately toward the one-direction side and the other-direction side as in the sixth exemplary embodiment.

Thus in the sixth exemplary embodiment, similarly to in Reference Example 4, preferably the threshold of the physical property value is changed according to the operation mode of the hose 1.

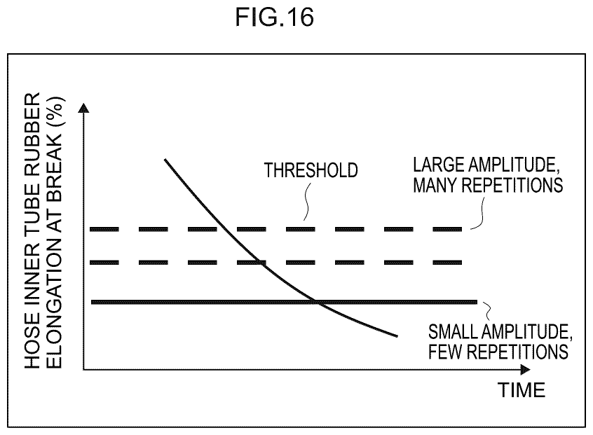

More specifically, in cases in which the hose 1 is used with a distance between a length direction one-end portion and other-end portion that changes in magnitude so as to deform in a convex shape alternately toward the one-direction side and the other-direction side, the threshold is shifted upward more the greater the amplitude of the hose 1 and the greater the number of repetitions, as illustrated in FIG. 16.

As an amount to shift the threshold, the threshold may be set by employing a hose of the same type to the in-service hose 1, creating the deterioration model by moving this hose the same as the in-service hose 1, and taking the operating time at the point in time when the hose of the deterioration model malfunctions (as an example cracks develop and fluid leaks) as the usage limit, and storing this threshold in the remaining service life prediction section 44.

### Supplement 13

A hose remaining service life prediction method to predict a remaining service life of an in-service hose at least including an inner tube rubber layer having an inside portion contacted by a fluid and used with a distance between a length direction one-end portion and other-end portion that changes in magnitude so as to deform in a convex shape alternately toward a one-direction side and an other-direction side, and including a reinforcement layer disposed further to an outside periphery than the inner tube rubber layer. The hose remaining service life prediction method includes a deterioration model creation process that in advance, for a hose of the same type and same operation mode to the in-service hose, uses the fluid to find a relationship of the inner tube rubber layer between an operating time and the physical property value of the rubber configuring the inner tube rubber layer and to create a deterioration model of the inner tube rubber layer, includes an operating time calculation process that for the in-service hose calculates an operating time of the inner tube rubber layer from start of use up to when the prediction is performed, includes a threshold setting process in which a threshold of the physical property value is set as a usage limit of the inner tube rubber layer according a number of repetitions of bending the inner tube rubber layer due to changing the distance, and includes a remaining service life prediction process that considers the operating time calculated in the operating time calculation section and the deterioration model created in the deterioration model creation section and predicts a duration from an operating time elapsed time up to an operating time attainment time when the physical property value will attain the threshold in the deterioration model as the remaining service life of the in-service hose.

### Supplement 14

A hose remaining service life prediction system to predict a remaining service life of an in-service hose at least including an inner tube rubber layer having an inside portion contacted by a fluid and used with a distance between a length direction one-end portion and other-end portion that changes in magnitude so as to deform in a convex shape alternately toward a one-direction side and an other-direction side, and including a reinforcement layer disposed further to an outside periphery than the inner tube rubber layer. The hose remaining service life prediction system includes a deterioration model creation section that, for a hose of the same type and same operation mode to the in-service hose, uses the fluid to find a relationship of the inner tube rubber layer between an operating time and the physical property value of the rubber configuring the inner tube rubber layer and to create a deterioration model of the inner tube rubber layer, includes an operating time calculation section that for the in-service hose calculates an operating time of the inner tube rubber layer up to when the prediction is performed, includes a threshold setting process in which a threshold of the physical property value is set as a usage limit of the inner tube rubber layer according a number of repetitions of bending the inner tube rubber layer due to changing the distance, and includes a remaining service life prediction section that considers the operating time calculated in the operating time calculation section and the deterioration model created in the deterioration model creation section and predicts a duration from an operating time elapsed time up to an operating time attainment time when the physical property value will attain the threshold in the deterioration model as the remaining service life of the in-service hose.

### Other Exemplary Embodiments

Although exemplary embodiments of the present disclosure have been described, the present disclosure is not limited thereto, and obviously other than these, various modifications may be implemented within a range not departing from a spirit thereof.

Although preferably creating the deterioration model using fluid at a similar temperature to the in-service hose 1 for a case of an operation mode in which deterioration of the rubber is promoted by temperature has been described for the first exemplary embodiment, similar also applies in relation to the second to sixth exemplary embodiments.

Moreover, the hose remaining service life prediction method and the hose remaining service life prediction system of the first exemplary embodiment may, as required, be combined with a hose remaining service life prediction method and a hose remaining service life prediction system of the second to sixth exemplary embodiments. Moreover, as required, any two or more of the hose remaining service life prediction method and hose remaining service life prediction system of the first exemplary embodiment to the sixth exemplary embodiment may be combined as appropriate.

The entire content of the disclosures of Japanese Patent Application Nos. 2021-130275, 2021-130276, 2021-130277, 2021-130278, 2021-130279, and 2021-130280 filed on Aug. 6, 2021 are incorporated by reference in the present specification.

All publications, patent applications and technical standards mentioned in the present specification are incorporated by reference in the present specification to the same extent as if each individual publication, patent application, or technical standard was specifically and individually indicated to be incorporated by reference.

1. A hose remaining service life prediction method that makes a prediction as to a remaining service life of an in-service hose including at least an inner tube rubber layer including a rubber having an inside portion contacted by a fluid and having a physical property value that changes with time, and a reinforcement layer disposed further toward an outer periphery than the inner tube rubber layer, the hose remaining service life prediction method comprising:
a deterioration model creation process that, for a same kind of hose as the in-service hose, uses the fluid to find a relationship between an operating time and the physical property value of the rubber of the inner tube rubber layer and to create a deterioration model of the inner tube rubber layer;
an operating time calculation process that, for the in-service hose, calculates an operating time of the inner tube rubber layer from start of use until a time at which the prediction is performed; and
a remaining service life prediction process that predicts the remaining service life of the in-service hose based on the operating time calculated in the operating time calculation process and on the deterioration model created in the deterioration model creation process.

2. The hose remaining service life prediction method of claim 1, wherein:
an additive is added to the fluid; and
the inner tube rubber layer includes a rubber that is affected by the additive.

3. The hose remaining service life prediction method of claim 1, wherein:
the inner tube rubber layer includes a rubber that is affected by a physical property of the fluid.

4. The hose remaining service life prediction method of claim 1, wherein:
the fluid is a fluid that deteriorates with time; and
the inner tube rubber layer includes a rubber that is affected by the fluid that has deteriorated with time.

5. The hose remaining service life prediction method of claim 1, further comprising:
a threshold setting process in which a threshold of the physical property value is set as a usage limit of the inner tube rubber layer in accordance with a magnitude of strain arising in the inner tube rubber layer,
wherein the remaining service life prediction process considers the operating time calculated in the operating time calculation process and the deterioration model created in the deterioration model creation process, and predicts a duration from an operating time elapsed time until an operating time attainment time at which the physical property value will attain the threshold in the deterioration model as the remaining service life of the in-service hose.

6. The hose remaining service life prediction method of claim 1, wherein:
the inner tube rubber layer is used with a distance between one end portion and another end portion in a length direction changing in magnitude so as to form a convex shape toward one direction;
the hose remaining service life prediction method further comprises a threshold setting process that sets a threshold of the physical property value as a usage limit of the inner tube rubber layer in accordance with a change amount of the distance of the inner tube rubber layer and a number of repetitions of bending the inner tube rubber layer as a result of changing the distance; and
the remaining service life prediction process considers the operating time calculated in the operating time calculation process and the deterioration model created in the deterioration model creation process, and predicts a duration from an operating time elapsed time until an operating time attainment time at which the physical property value will attain the threshold in the deterioration model as the remaining service life of the in-service hose.

7. The hose remaining life prediction method of claim 1, wherein:
the inner tube rubber layer is used with a distance between one end portion and another end portion in a length direction changing in magnitude so as to deform in a convex shape alternately toward a side in one direction and a side in another direction;
the hose remaining service life prediction method further comprises a threshold setting process that sets a threshold of the physical property value as a usage limit of the inner tube rubber layer in accordance with a number of repetitions of bending the inner tube rubber layer as a result of changing the distance; and
the remaining service life prediction process considers the operating time calculated in the operating time calculation process and the deterioration model created in the deterioration model creation process, and predicts a duration from an operating time elapsed time until an operating time attainment time at which the physical property value will attain the threshold in the deterioration model as the remaining service life of the in-service hose.

8. A hose remaining service life prediction system that makes a prediction as to a remaining service life of an in-service hose including at least an inner tube rubber layer including a rubber having an inside portion contacted by a fluid and having a physical property value that changes with time, and a reinforcement layer disposed further toward an outer periphery than the inner tube rubber layer, the hose remaining service life prediction system comprising:
a deterioration model creation section that, for a same kind of hose as the in-service hose, uses the fluid to find a relationship between an operating time and the physical property value of the rubber of the inner tube rubber layer and to create a deterioration model of the inner tube rubber layer;
an operating time calculation section that, for the in-service hose, calculates an operating time of the inner tube rubber layer from start of use until a time at which the prediction is performed; and
a remaining service life prediction section that predicts the remaining service life of the in-service hose based on the operating time calculated by the operating time calculation section and on the deterioration model created by the deterioration model creation section.

9. The hose remaining service life prediction system of claim 8, wherein:
an additive is added to the fluid; and
the inner tube rubber layer includes a rubber that is affected by the additive.

10. The hose remaining service life prediction system of claim 8, wherein:
the inner tube rubber layer includes a rubber that is affected by a physical property of the fluid.

11. The hose remaining service life prediction system of claim 8, wherein:
the fluid is a fluid that deteriorates with time; and
the inner tube rubber layer includes a rubber that is affected by the fluid that has deteriorated with time.

12. The hose remaining service life prediction system of claim 8, further comprising:
a threshold setting section that sets a threshold of the physical property value as a usage limit of the inner tube rubber layer in accordance with a magnitude of strain arising in the inner tube rubber layer,
wherein the remaining service life prediction section considers the operating time calculated by the operating time calculation section and the deterioration model created by the deterioration model creation section, and predicts a duration from an operating time elapsed time until an operating time attainment time at which the physical property value will attain the threshold in the deterioration model as the remaining service life of the in-service hose.

13. The hose remaining service life prediction system of claim 8, wherein:
the inner tube rubber layer is used with a distance between one end portion and another end portion in a length direction changing in magnitude so as to form a convex shape toward one direction;
the hose remaining service life prediction system further comprises a threshold setting section that sets a threshold of the physical property value as a usage limit of the inner tube rubber layer in accordance with a change amount of the distance of the inner tube rubber layer and a number of repetitions of bending the inner tube rubber layer as a result of changing the distance; and
the remaining service life prediction section considers the operating time calculated by the operating time calculation process and the deterioration model created by the deterioration model creation section, and predicts a duration from an operating time elapsed time until an operating time attainment time at which the physical property value will attain the threshold in the deterioration model as the remaining service life of the in-service hose.

14. The hose remaining life prediction system of claim 8, wherein:
the inner tube rubber layer is used with a distance between one end portion and another end portion in a length direction changing in magnitude so as to deform in a convex shape alternately toward a side in one direction and a side in another direction;
the hose remaining service life prediction system further comprises a threshold setting process that sets a threshold of the physical property value as a usage limit of the inner tube rubber layer in accordance with a number of repetitions of bending the inner tube rubber layer as a result of changing the distance; and
the remaining service life prediction section considers the operating time calculated by the operating time calculation section and the deterioration model created by the deterioration model creation section, and predicts a duration from an operating time elapsed time until an operating time attainment time at which the physical property value will attain the threshold in the deterioration model as the remaining service life of the in-service hose.
